(19) United States
(12) Patent Application Publication
(10) Pub. No.: US 2009/0236143 A1
(43) Pub. Date: Sep. 24, 2009

(54) Multilayer wiring board, multilayer wiring board unit and electronic device

(75) Inventor: Naoki Nakamura, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/292,845

(22) Filed: Nov. 26, 2008

(30) Foreign Application Priority Data
Mar. 24, 2008 (JP) 2008-076173

(51) Int. Cl. H05K 1/11; H05K 5/00

(52) U.S. Cl. 174/520; 174/261

(57) ABSTRACT

A multilayer wiring board that includes multiple wiring layers, multiple insulating layers stacked alternately with the multiple wiring layers to form a multilayer structure, a first via, and a second via. The first via is in the shape of a recess and made of a conductor covering an inner surface of a hole penetrating through insulating layers and having a bottom on an inner wiring layer of the wiring layers that has insulating layers on both the upper and lower sides thereof. The second via is in the shape of a recess and made of a conductor covering an inner surface of a hole penetrating through insulating layers in the direction opposite to the direction of the hole for the first via and having a bottom on the inner wiring layer at a position corresponding to the bottom of the hole for the first via.

### CROSS-REFERENCE TO RELATED APPLICATION

This application is based upon and claims the benefit of priority of the prior Japanese Patent Application No. 2008-076173, filed on Mar. 24, 2008, the entire contents of which are incorporated herein by reference.

### FIELD

Embodiments discussed herein are directed to a multilayer wiring board having a multilayer structure in which multiple wiring layers and multiple insulating layers are alternately stacked one on another, a multilayer wiring board unit having such a multilayer wiring board and an electronic component mounted thereon, and an electronic device incorporating such a multilayer wiring board unit.

### BACKGROUND

In recent years, electronic devices required to have high mobility, such as cellular phones, have been remarkably reduced in size and weight. Many of such electronic devices incorporate the so-called build-up substrate as a multilayer wiring board on which an electronic component is mounted (see Japanese Laid-open Patent Application Publication No. 2005-500567 and Japanese Laid-open Patent Publication No. 2000-91754, for example).

FIG. 15 is a diagram illustrating an example of the build-up substrate, and FIG. 16 is a diagram illustrating another example of the build-up substrate, which is different from the example illustrated in FIG. 15.

FIG. 15 is a cross-sectional view of a first build-up substrate 500, and FIG. 16 is a cross-sectional view of a second build-up substrate 600.

The substrate 500, 600 has a core layer 510, 610 that has a base insulating layer 511, 611 and wiring layers 512, 612 on the opposite front and back surfaces thereof, and insulating layers 521, 621 and wiring layers 522, 622 are alternately stacked on each of the front and back surfaces of the core layer 510, 610.

The wiring layers 512, 522, 612 and 622 have conductor patterns 512a, 522a, 612a and 622a, respectively. Furthermore, the wiring layers 512, 522, 612 and 622 have insulating parts 512b, 522b, 612b and 622b, respectively, which are made of the same insulating material as the insulating material of the insulating layers 521, 621 and fill the gaps between the conductors of the conductor patterns of the respective wiring layers. In the case where the build-up substrate 500, 600 is manufactured by a typical stacking process in which an insulating layer is stacked on a wiring layer having a conductor pattern, and the stack is heated under pressure, these insulating parts are formed by some of the insulating material forming the insulating layer penetrating into the gaps between the conductors of the conductor pattern. However, the wiring layers forming the front and back surfaces of the build-up substrate are composed only of the conductor pattern because no insulating layer is stacked thereon, so that no insulating material penetrates into the gaps between the conductors.

Furthermore, the substrate 500, 600 has minute vias 530, 630 having a diameter of about 100 μm that electrically connect adjacent wiring layers. The electrical connections between the wiring layers are established by the vias 530, 630 in contact with the conductor patterns of the wiring layers.

Each via 530, 630 is formed by plating the inner surface of a hole penetrating through one insulating layer from a wiring layer to an adjacent wiring layer with a conductor. Each via 530, 630 is composed of a plating layer 531, 631 having the shape of a recess conforming to the inner surface of the hole and a filling part 532, 632 that is made of the same conductor as the plating layer 531, 631 and fills the recess of the plating layer 531, 631.

In the substrate 500, 600, electrical connection between wiring layers spaced apart from each other with one or more other wiring layers interposed therebetween is essentially established by multiple vias 530, 630 stacked between the wiring layers in the thickness direction thereof. As described above, the recess of the plating layer 531, 631 of each via 530, 630 is filled with the filling part 532, 632. Thus, if multiple vias 530, 630 are stacked in such a manner that the bottom of a via 530, 630 is in contact with the filling part 532, 632 of an adjacent via 530, 630 as illustrated in FIGS. 15 and 16, multiple vias 530, 630 are electrically connected to each other, and the electrical connection between the two wiring layers described above is established. However, two vias 530, 630 adjacent to each other with the wiring layer 512, 612 of the core layer 510, 610 interposed therebetween are not in direct contact with each other, and the electrical connection between the vias 530, 630 is established by the contact of the bottoms of the vias 530, 630 facing each other with the wiring layer 512, 612.

For example, in the first build-up substrate 500 illustrated in FIG. 15, the wiring layer 522 forming a front surface 500a illustrated at the top in the drawing and the wiring layer 522 forming a back surface 500b illustrated at the bottom in the drawing are electrically connected to each other by seven vias 530 stacked in the thickness direction. In the second build-up substrate 600 illustrated in FIG. 16, the wiring layer 622 forming a back surface 600b illustrated at the bottom in the drawing and the wiring layer 612 of the core layer 610 closer to the back surface 600b are electrically connected to each other by three vias 630 stacked in the thickness direction.

Furthermore, in the second build-up substrate 600 illustrated in FIG. 16, there are a skip via 640 equivalent to two vias 630 that electrically connects one of the two wiring layers 612 of the core layer 610 and a wiring layer 622 spaced apart from the wiring layer 612 with the other wiring layer 612 interposed therebetween and a penetrating via 650 equivalent to three vias 630 that electrically connects two wiring layers 622 spaced apart from each other with the core layer 610 interposed therebetween.

The skip via 640 is formed by plating the inner surface of a hole extending from the wiring layer 622 to the wiring layer 612 of the core layer 610 with a conductor, so that the skip via 640 is made of the conductor covering the inner surface of the hole and has the shape of a recess conforming to the inner surface. Furthermore, unlike the vias 530, 630, the recess of the skip via 640 is not filled with the conductor but filled with the insulating material of the insulating layer 521, 621 covering the opening of the skip via 640 and penetrating into the recess during manufacture. The penetrating via 650 is formed by plating the inner surface of a through-hole penetrating from one of the wiring layers 622 to the other wiring layer 622 with a conductor, is made of the conductor covering the inner surface of the through-hole, and have the shape of a through-hole. The through-hole of the penetrating via 650 is filled with the insulating material of the insulating layer 521, 621 covering the openings in the front and back surfaces and penetrating into the through-hole during manufacture. In the second build-up substrate 600 illustrated in FIG. 16, since the recess of the skip via 640 and the through-hole of the penetrating via 650 are filled with the insulating material, the recess and the through-hole do not remain hollow to form a void in the substrate, so that problems, such as occurrence of a crack due to thermal expansion of air in the void or the like, is avoided.

In some conventional build-up substrates, the skip via or penetrating via described above is used to establish electrical connections between wiring layers. However, in many conventional build-up substrates, electrical connections between wiring layers are established by multiple vias stacked between the wiring layers to be connected as illustrated in FIGS. 14 and 15. These vias are composed of a plating layer and a filling part made of a conductor and filling the recess of the plating layer as described above. Conventionally, conductor plating is used to fill such a recess (see Japanese Patent No. 3126060, for example).

In order to form the via described above, conductor plating has to be conducted multiple times including the conductor plating for forming the plating layer and the conductor plating for filling the recess of the plating layer to form the filling part. This increases the cost of the multilayer wiring board having a via.

### SUMMARY

According to an aspect of the invention, a multilayer wiring board includes: multiple wiring layers; multiple insulating layers that are stacked alternately with the multiple wiring layers to form a multilayer structure; a first via made of a conductor covering an inner surface of a hole penetrating through multiple insulating layers and having a bottom on an inner wiring layer of the multiple wiring layers, the inner wiring layer having multiple insulating layers on both the upper and lower sides thereof in the multilayer structure, and the first via having the shape of a recess conforming to the inner surface; and a second via made of a conductor covering an inner surface of a hole penetrating through multiple insulating layers in the direction opposite to the direction of the hole for the first via and having a bottom on the inner wiring layer at a position corresponding to the bottom of the hole for the first via, the second via having the shape of a recess conforming to the inner surface.

### BRIEF DESCRIPTION OF DRAWINGS

FIG. 1 is a schematic diagram illustrating a cellular phone, which is a specific example of an electronic device;

FIGS. 2A and 2B are schematic diagrams illustrating a circuit board, which is a specific example of a multilayer wiring board unit;

FIG. 3 is a schematic cross-sectional view of a multilayer wiring board 300 illustrated in FIG. 2;

FIG. 4 is a diagram illustrating another example of the multilayer wiring board, in which vias having openings in wiring layers forming the front and back surfaces remain hollow;

FIG. 5 is a diagram illustrating examples of electrical connection between a wiring layer 322 forming a front surface 300a and a wiring layer 322 forming a back surface 300b;

FIG. 6 is a diagram illustrating examples of electrical connection between the wiring layer 322 forming the front surface 300a and the second wiring layer 322 from the back surface 300b and examples of electrical connection between the wiring layer 322 forming the front surface 300a and the third wiring layer 322 from the back surface 300b;

FIG. 7 is a diagram illustrating examples of electrical connection between the second wiring layer 322 from the front surface 300a and the second wiring layer 322 from the back surface 300b;

FIG. 8 is a diagram for illustrating processing in steps S1 to S3 in a method of manufacturing the multilayer wiring board 300;

FIG. 9 is a diagram for illustrating processing in steps S4 to S6 in the method of manufacturing the multilayer wiring board 300;

FIG. 10 is a diagram for illustrating processing in steps S7 and S8 in the method of manufacturing the multilayer wiring board 300;

FIG. 11 is a diagram for illustrating processing in step S9 in the method of manufacturing the multilayer wiring board 300;

FIG. 12 is a diagram for illustrating processing in step S10 in the method of manufacturing the multilayer wiring board 300;

FIG. 13 is a diagram for illustrating processing in step S11 in the method of manufacturing the multilayer wiring board 300;

FIG. 14 is a diagram for illustrating processing in step S12 in the method of manufacturing the multilayer wiring board 300;

FIG. 15 is a diagram illustrating an example of a build-up substrate; and

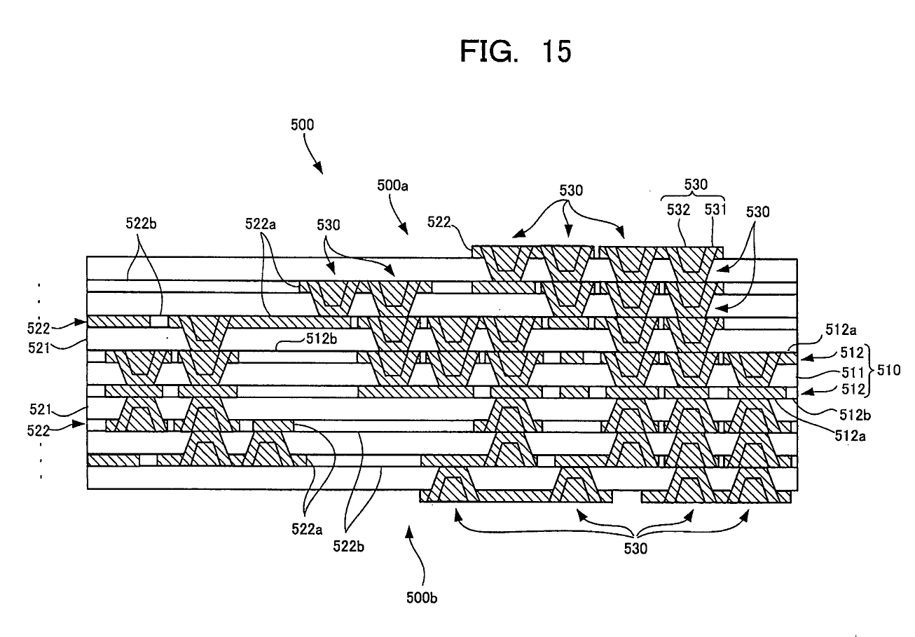

FIG. 16 is a diagram illustrating another example of the build-up substrate, which is different from the example illustrated in FIG. 15.

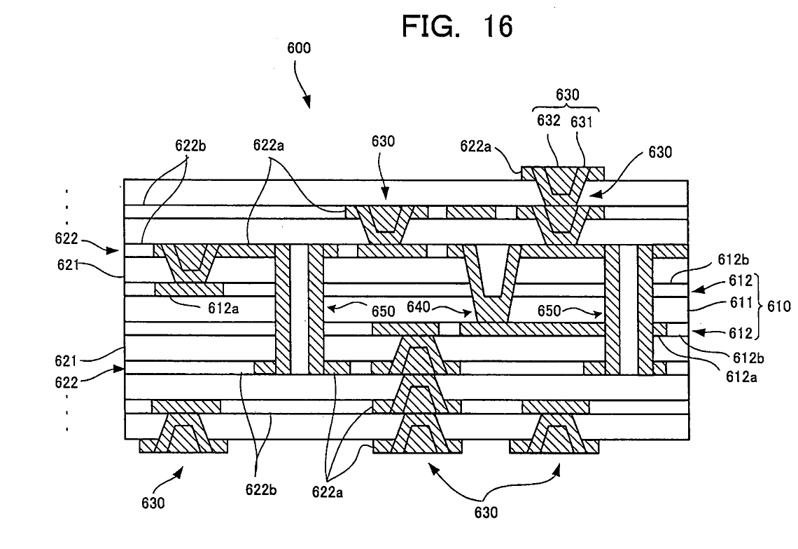

### DESCRIPTION OF EMBODIMENT(S)

In the following, a multilayer wiring board, a multilayer wiring board unit and an electronic device according to embodiments of the present invention, essential structures of which have been described above, will be described specifically with reference to the drawings.

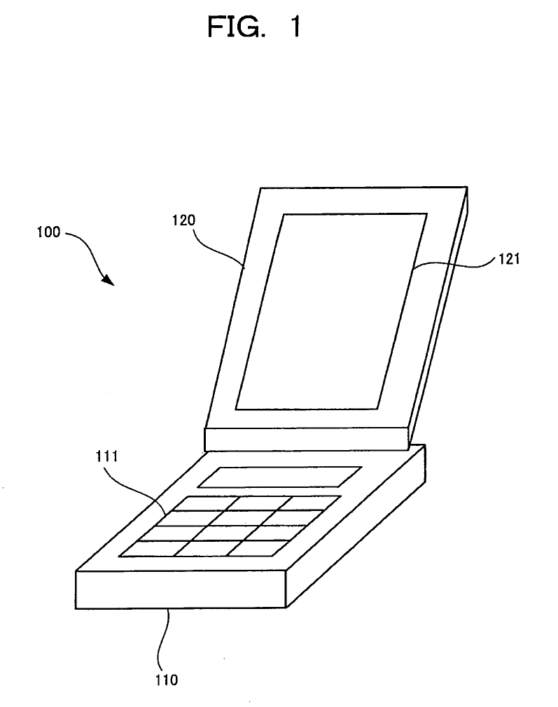

FIG. 1 is a schematic diagram illustrating a cellular phone, which is a specific example of an electronic device according to an embodiment of the present invention.

A cellular phone 100 illustrated in FIG. 1 has a first portion 110 including various operation keys 111 operated by a user, and a second portion 120 that is rotatably connected to the first portion 110 and includes a liquid crystal display 121 on which various kinds of information are displayed. In this embodiment, as described later, the first portion 110 incorporates a circuit board, which is a specific example of a multilayer wiring board unit according to an embodiment of the present invention.

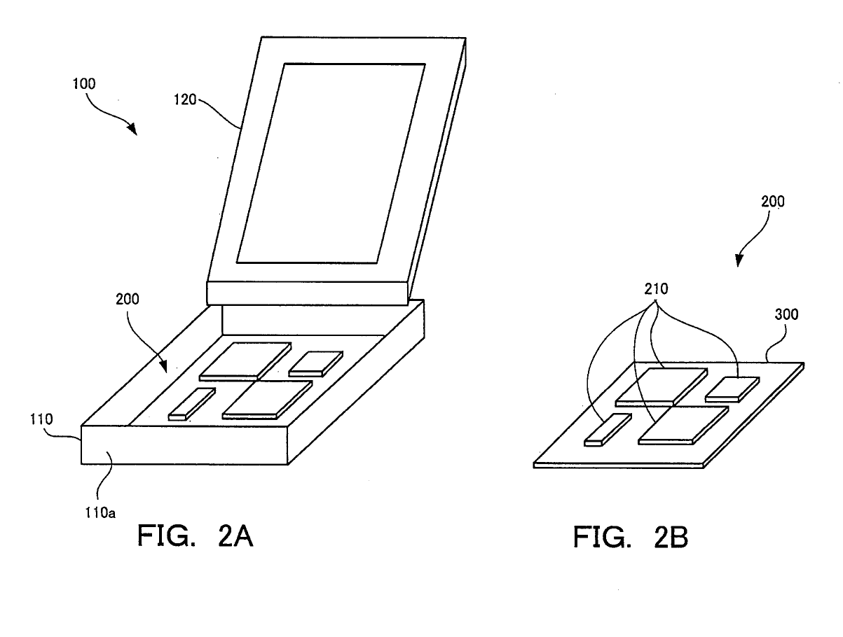

FIG. 2 includes schematic diagrams for illustrating a circuit board, which is a specific example of a multilayer wiring board unit according to an embodiment of the present invention.

FIG. 2A illustrates the cellular phone 100 with an upper surface panel having the operation keys 111 removed from a housing 110a of the first portion 110 so that a circuit board 200 incorporated therein is exposed. FIG. 2B illustrates the circuit board 200 separately. The housing 110a illustrated in FIG. 2A is an example of the housing in the essential structure of the electronic device described earlier.

The circuit board 200 illustrated in FIG. 2 is composed of a multilayer wiring board 300, which is a specific example of a multilayer wiring board according to an embodiment of the present invention, the essential structure of which has been described earlier, and multiple electronic components 210 mounted thereon. The multilayer wiring board 300 is a build-up substrate that has a multilayer structure in which multiple wiring layers and multiple insulating layers alternately stacked one on another and minute vias for interconnecting the wiring layers having a diameter of about 100 μm are formed. The multilayer wiring board 300 is an example of the multilayer wiring board in the essential structures of the multilayer wiring board unit and the electronic device described earlier, and the electronic component 210 is an example of the electronic component in the same essential structures.

In the following, the multilayer wiring board 300 will be described in detail.

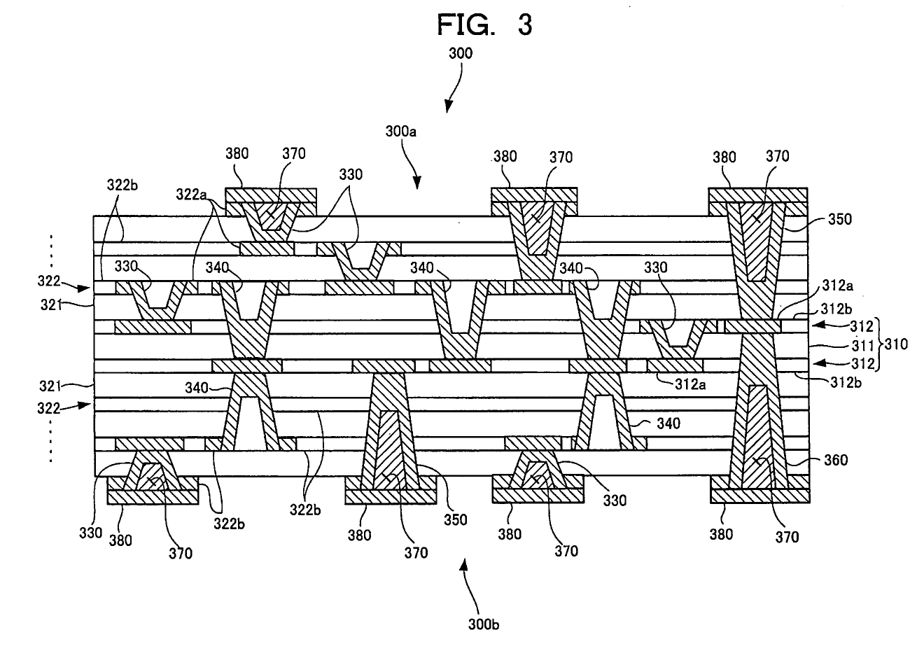

FIG. 3 is a schematic cross-sectional view of the multilayer wiring board 300 illustrated in FIG. 2.

As illustrated in FIG. 3, the multilayer wiring board 300 has a core layer 310 including a base insulating layer 311 and wiring layers 312 disposed on the opposite front and back surfaces of the base insulating layer 311, and insulating layers 321 and wiring layers 322 are alternately stacked on each of the front and back surfaces of the core layer 310. The wiring layers 312 and 322 have conductor patterns 312a and 322a, respectively. The wiring layers 312 and 322 further have insulating parts 312b and 322b, respectively, which are made of the same insulating material as the insulating layers 321 and fill gaps between the conductors of the respective conductor patterns. This is because the multilayer wiring board 300 is manufactured by pressing the wiring layers 312 and 322 having conductor patterns and the insulating layers 321 formed thereon together, and some of the insulating material forming the insulating layers 321 penetrates into gaps between the conductors of the conductor patterns 312a and 322a during pressing, as described later. However, the wiring layers 322 forming the front and back surfaces of the multilayer wiring board 300 are composed only of the respective conductor patterns 322a because no insulating layer 321 is stacked thereon, and no insulating material penetrates into the gaps between the conductors.

The wiring layers including the wiring layers 312 of the core layer 310 and the other wiring layers 322 are examples of the multiple wiring layers in the essential structures of the multilayer wiring board, the multilayer wiring board unit and the electronic device described earlier. The insulating layers including the insulating layer 311 of the core layer 310 and the other insulating layers 321 are examples of the multiple insulating layers in the same essential structures.

The multilayer wiring board 300 illustrated in FIG. 3 further has an adjacent via 330 that electrically connects adjacent wiring layers 312, 322 to each other, a one-layer-skip via 340 that electrically connects two wiring layers 312, 322 to each other by skipping one wiring layer 312, 322, a two-layer-skip via 350 that electrically connects two wiring layers 312, 322 to each other by skipping two wiring layers 312, 322, and a three-layer-skip via 360 that electrically connects two wiring layers 312, 322 to each other by skipping three wiring layers 312, 322. Each via 340, 350, 360 is formed by plating the inner surface of a hole penetrating through the insulating layer between the two wiring layers 312, 322 to be connected and has the shape of a recess conforming to the inner surface of the hole.

In this embodiment, of the vias 340, 350 and 360, the vias that open in the wiring layers 312, 322 other than the wiring layers 322 forming the front and back surfaces of the multilayer wiring board 300 are filled with the insulating material of the insulating layers 322 covering the openings and penetrating into the vias during manufacture of the multilayer wiring board 300 described later. As a result, the problem that the hollow recesses of the vias remain in the multilayer wiring board 300 to form voids, and a crack occurs because of thermal expansion of the air in the voids or the like is effectively solved.

On the other hand, the recesses of the vias opening in the wiring layers 322 forming the front and back surfaces of the multilayer wiring board 300 are filled with a predetermined resin material 370, and the openings are covered with a conductor film 380. In this embodiment, the conductor films 380 covering the openings are used as lands for mounting of the electronic components 210 illustrated in FIG. 2 on the multilayer wiring board 300.

Furthermore, in the multilayer wiring board 300, electrical connection between wiring layers 322 on the opposite sides of the core layer 310 is established by two vias stacked between the wiring layers 322 to be connected. The two vias are electrically connected to each other by the bottoms of the two vias facing each other with an isolated pattern in a wiring layer 322 and being in contact with the isolated pattern, so that the wiring layers 322 to be connected are electrically connected to each other.

In the example illustrated in FIG. 3, the third wiring layer 322 from a front surface 300a illustrated at the top in the drawing and the second wiring layer 322 from a back surface 300b illustrated at the bottom in the drawing are electrically connected to each other by two one-layer-skip vias 340 stacked between the wiring layers 322 with an isolated pattern in the wiring layer 312 of the core layer 310 closer to the back surface 300b interposed therebetween. Furthermore, the wiring layer 322 forming the front surface 300a and the wiring layer 322 forming the back surface 300b are electrically connected to each other by the two-layer-skip via 350 and the three-layer-skip via 360 stacked between the wiring layers 322 with an isolated pattern in the wiring layer 312 of the core layer 310 closer to the front surface 300a interposed therebetween.

In the example illustrated in FIG. 3, one of the two one-layer-skip vias 340 electrically connecting the third wiring layer 322 from the front surface 300a and the second wiring layer 322 from the back surface 300b is an example of the first via in the essential structures of the multilayer wiring board, the multilayer wiring board unit and the electronic device described earlier, and the other via is an example of the second via in the same essential structures. Furthermore, one of the two-layer-skip via 350 and the three-layer-skip via 360 electrically connecting the wiring layer 322 forming the front surface 300a and the wiring layer 322 forming the back surface 300b is also an example of the first via in the same essential structures, and the other via is an example of the second via in the same essential structures. Furthermore, the wiring layer 312 of the core layer 310 closer to the back surface 300b and the wiring layer 312 of the core layer 310 closer to the front surface 300a are each an example of the inner wiring layer in the same essential structures.

In this embodiment, as illustrated in FIG. 3, the vias opening in the wiring layer 322 forming the front surface 300a or the wiring layer 322 forming the back surface 300b are filled with the predetermined resin material 370, and the openings are covered with the conductor film 380. However, in the case where the conductor films 380 covering the openings and used as lands in this embodiment are not necessary, these vias may remain hollow as in another example described below.

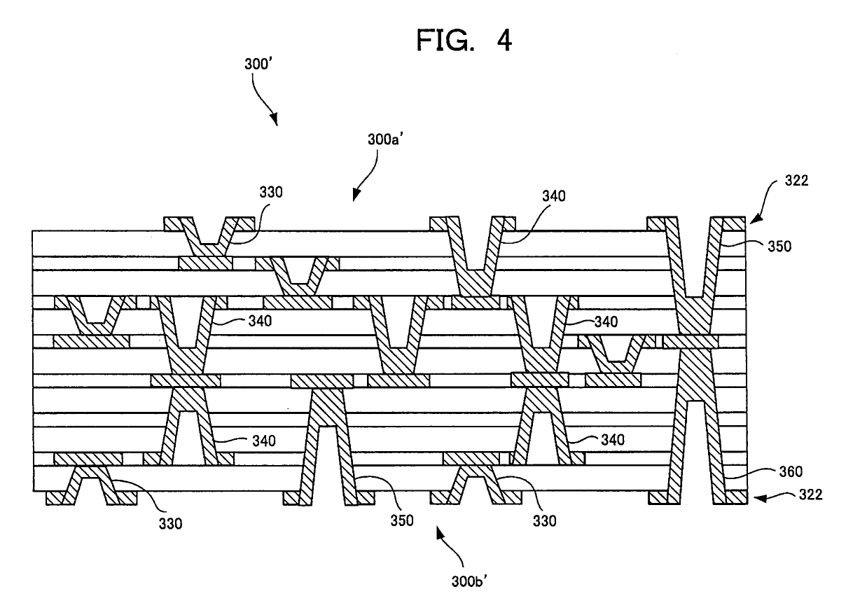

FIG. 4 is a diagram illustrating another example of the multilayer wiring board in which vias opening in the wiring layers forming the front and back surfaces of the multilayer wiring board remain hollow.

A multilayer wiring board 300′ according to this example illustrated in FIG. 4 is essentially equivalent to the multilayer wiring board 300 according to this embodiment illustrated in FIG. 3. In FIG. 4, components equivalent to those illustrated in FIG. 3 are denoted by the same reference numerals as those in FIG. 3, and redundant descriptions thereof will be omitted.

In the multilayer wiring board 300′ in this example, the adjacent vias 330, the one-layer-skip vias 340, the two-layer-skip vias 350 and the three-layer-skip vias 360 opening in the wiring layer 322 forming a front surface 300a′ and the wiring layer 322 forming a back surface 300b′ remain hollow. Since there is no possibility that a via having the opening exposed on the front or back surface forms a void, the via can remain hollow as in this example illustrated in FIG. 4 if the land described above is not necessary. Therefore, the trouble of filling the recesses is saved, and the cost is reduced accordingly.

Next, there will be described an exemplary electrical connection between wiring layers through vias used in designing the multilayer wiring board 300 according to this embodiment illustrated in FIG. 3. For the sake of simplicity of explanation, in the example described below, the resin material 370 filling the vias having the openings in the wiring layer 322 forming the front surface 300a and the wiring layer 322 forming the back surface 300b and the conductor films 380 covering the openings are omitted.

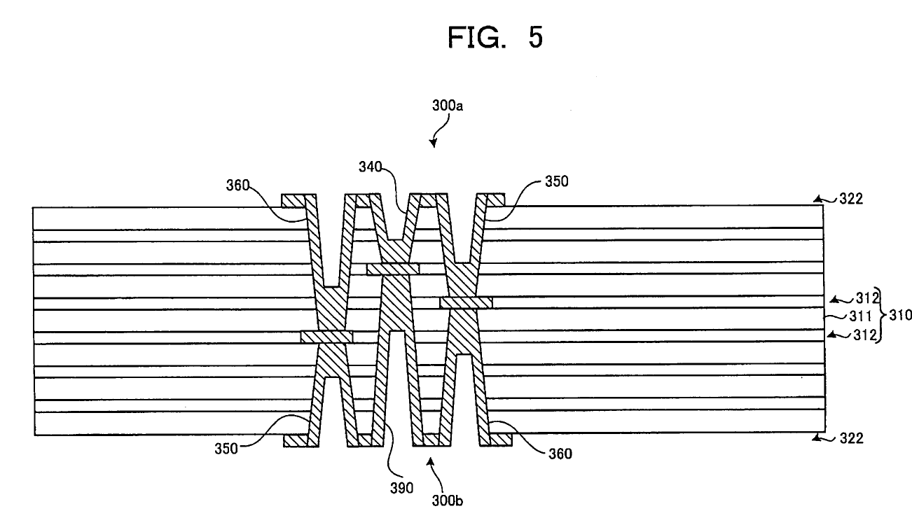

FIG. 5 is a diagram illustrating examples of electrical connection between the wiring layer 322 forming the front surface 300a and the wiring layer 322 forming the back surface 300b.

FIG. 5 illustrates three types of connections.

A first example is a connection through the three-layer-skip via 360 formed on the side of the front surface 300a and the two-layer-skip via 350 formed in the back surface 300b. In this example, the bottoms of the two vias face each other with an isolated pattern in the wiring layer 312 of the core layer 310 closer to the back surface 300b interposed therebetween and are in contact with the isolated pattern.

Furthermore, in this embodiment, a four-layer-skip via 390 that electrically connects two wiring layers 322 having the core layer 310 interposed therebetween to each other by skipping four wiring layers 312, 322 is also used. FIG. 5 also illustrates an example of connection using the one-layer-skip via 340 formed on the side of the front surface 300a and the four-layer-skip via 390 formed on the side of the back surface 300b. In this example, the bottoms of the two vias face each other with an isolated pattern in the third wiring layer 312 from the front surface 300a interposed therebetween and are in contact with the isolated pattern.

Furthermore, FIG. 5 illustrates an example of connection using the two-layer-skip via 350 formed on the side of the front surface 300a and the three-layer-skip via 360 formed on the side of the back surface 300b. In this example, the bottoms of the two vias face each other with an isolated pattern in the wiring layer 312 of the core layer 310 closer to the front surface 300a interposed therebetween and are in contact with the isolated pattern.

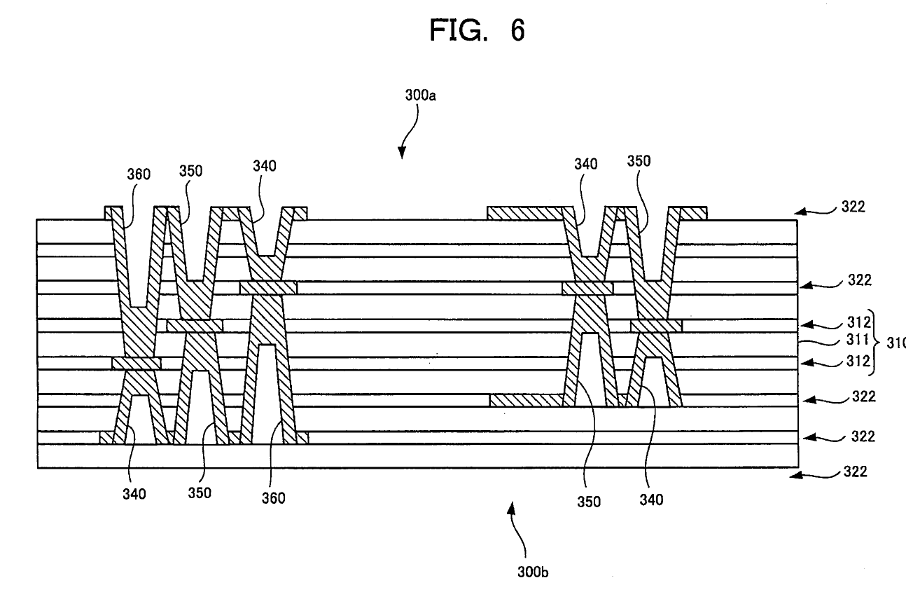

FIG. 6 is a diagram illustrating an example of electrical connection between the wiring layer 322 forming the front surface 300a and the second wiring layer 322 from the back surface 300b and an example of electrical connection between the wiring layer 322 forming the front surface 300a and the third wiring layer 322 from the back surface 300b. In this drawing, illustration of the conductor pattern of the wiring layer 322 forming the back surface 300b is omitted.

FIG. 6 illustrates three examples of connection between the wiring layer 322 forming the front surface 300a and the second wiring layer 322 from the back surface 300b.

A first example is a connection using the three-layer-skip via 360 formed on the side of the front surface 300a and the one-layer-skip via 340 formed on the side of the back surface 300b. The bottoms of the two vias are in contact with an isolated pattern in the wiring layer 312 of the core layer 310 closer to the back surface 300b. Another example is a connection using two two-layer-skip vias 350 formed on the side of the front surface 300a and the side of the back surface 300b. The bottoms of the two vias are in contact with an isolated pattern in the wiring layer 312 of the core layer 310 closer to the front surface 300a. A further example is a connection using the one-layer-skip via 340 formed on the side of the front surface 300a and the three-layer-skip via 360 formed on the side of the back surface 300b. The bottoms of the two vias are in contact with an isolated pattern in the third wiring layer 322 from the front surface 300a.

In addition, FIG. 6 illustrates two examples of connection between the wiring layer 322 forming the front surface 300a and the third wiring layer 322 from the back surface 300b.

A first example is a connection using the one-layer-skip via 340 formed on the side of the front surface 300a and the two-layer-skip via 350 formed on the side of the back surface 300b. The bottoms of the two vias are in contact with an isolated pattern in the third wiring layer 322 from the front surface 300a. Another example is a connection using the two-layer-skip via 350 formed on the side of the front surface 300a and the one-layer-skip via 340 formed on the side of the back surface 300b. The bottoms of the two vias are in contact with an isolated pattern in the wiring layer 312 of the core layer 310 closer to the front surface 300a.

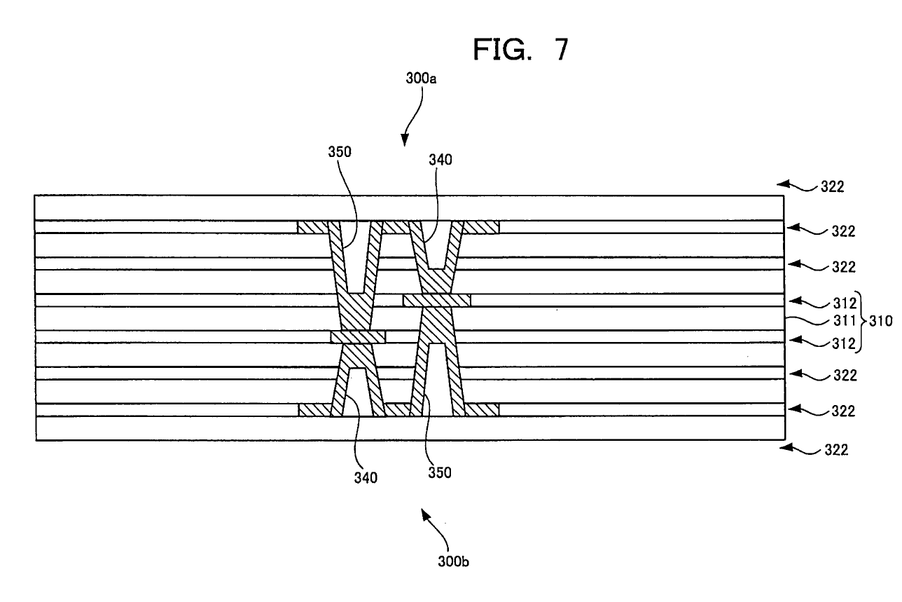

FIG. 7 is a diagram illustrating examples of electrical connection between the second wiring layer 322 from the front surface 300a and the second wiring layer 322 from the back surface 300b. In this drawing, illustration of the conductor patterns of the wiring layers 322 forming the front and back surfaces is omitted.

FIG. 7 illustrates two examples of connection.

A first example is a connection using the two-layer-skip via 350 formed on the side of the front surface 300a and the one-layer-skip via 340 formed on the side of the back surface 300b. In this example, the bottoms of the two vias are in contact with an isolated pattern in the wiring layer 312 of the core layer 310 closer to the back surface 300b. Another example is a connection using the one-layer-skip via 340 formed on the front surface 300a and the two-layer-skip via 350 formed on the back surface 300b. In this example, the bottoms of the two vias are in contact with an isolated pattern in the wiring layer 312 of the core layer 310 closer to the front surface 300a.

As described above with reference to FIGS. 5 to 7, according to this embodiment, the wiring layers 312, 322 in the multilayer wiring board 300 are electrically connected to each other in various combinations by two skip vias.

In the case where the vias are formed by plating the inner surfaces of the holes with a conductor as described above, the conductor plating becomes more difficult as the holes become deeper, and the cost can increase accordingly. In this embodiment, essentially, as illustrated in FIGS. 5 to 7, the two vias can be in contact with the isolated pattern in any of the wiring layers 312, 322 in the multilayer wiring board 300. Thus, in this embodiment, vias that lead to an extreme cost increase can be omitted by selecting the wiring layer including the isolated pattern so that the two vias used for the electrical connection have the same depth as far as possible in design of the multilayer wiring board 300.

Next, a method of manufacturing the multilayer wiring board 300 according to this embodiment illustrated in FIG. 3 will be described.

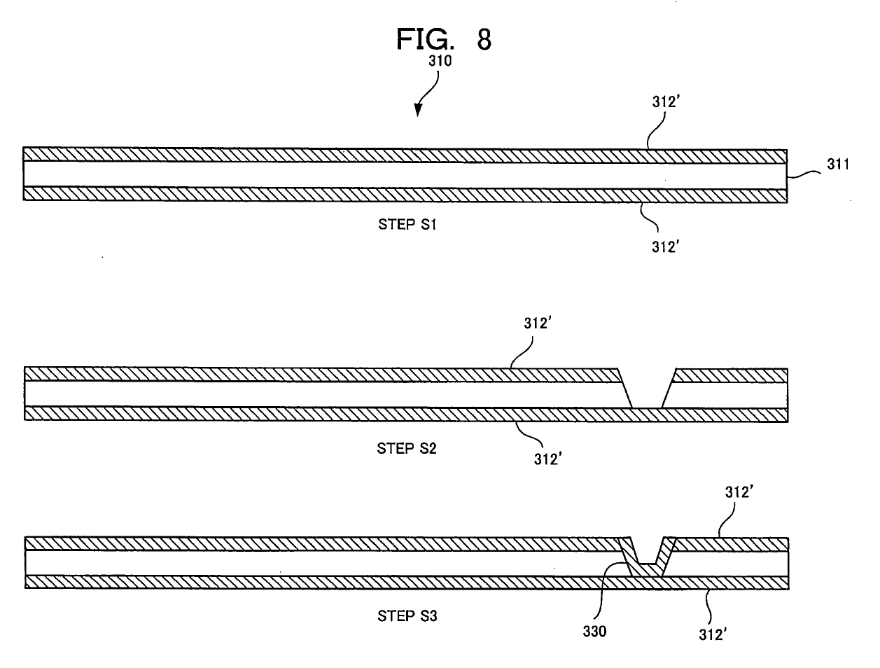

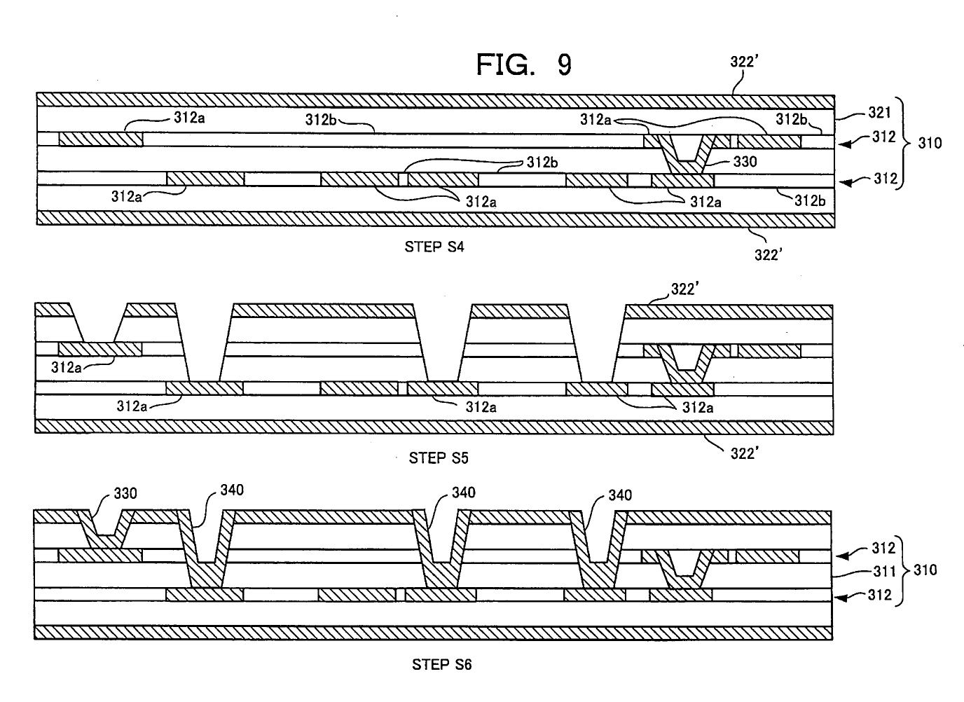

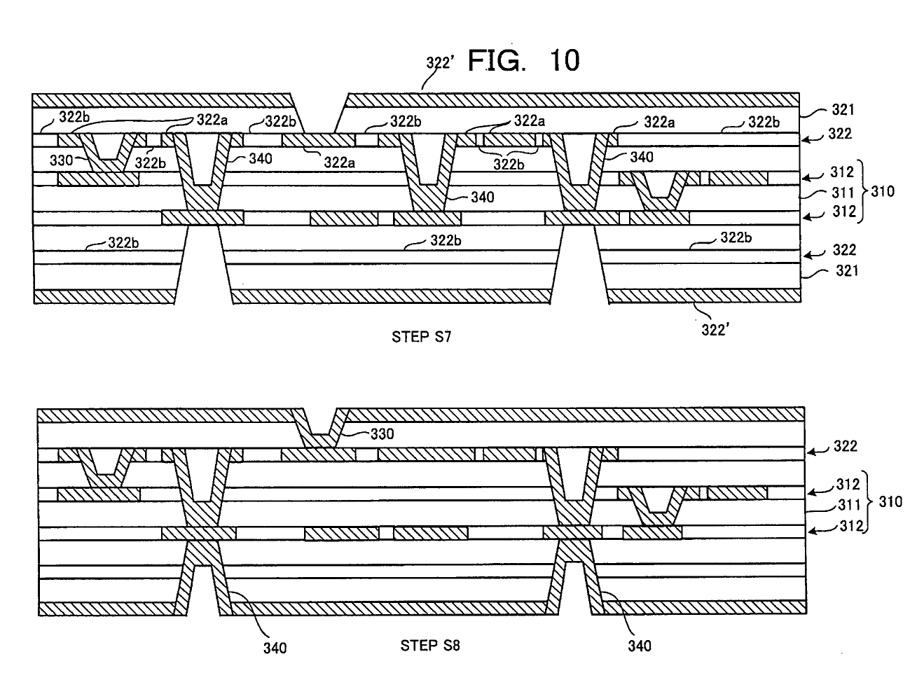

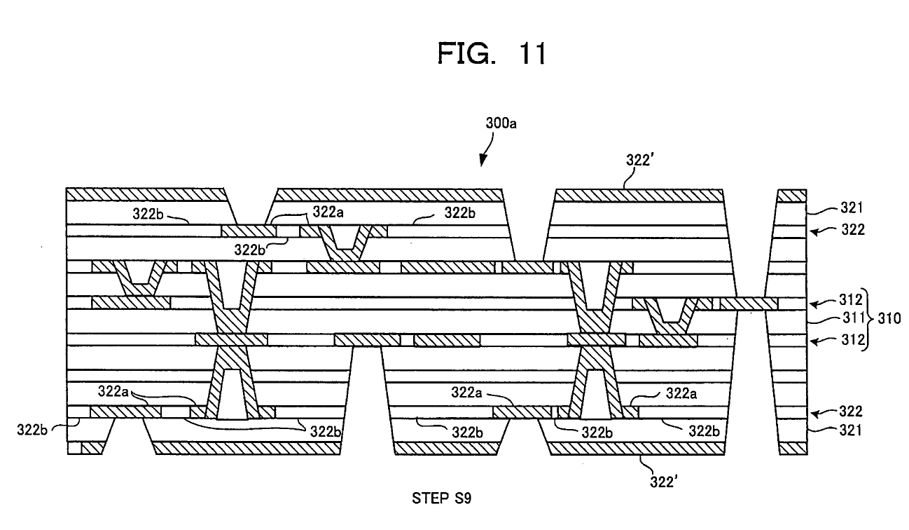

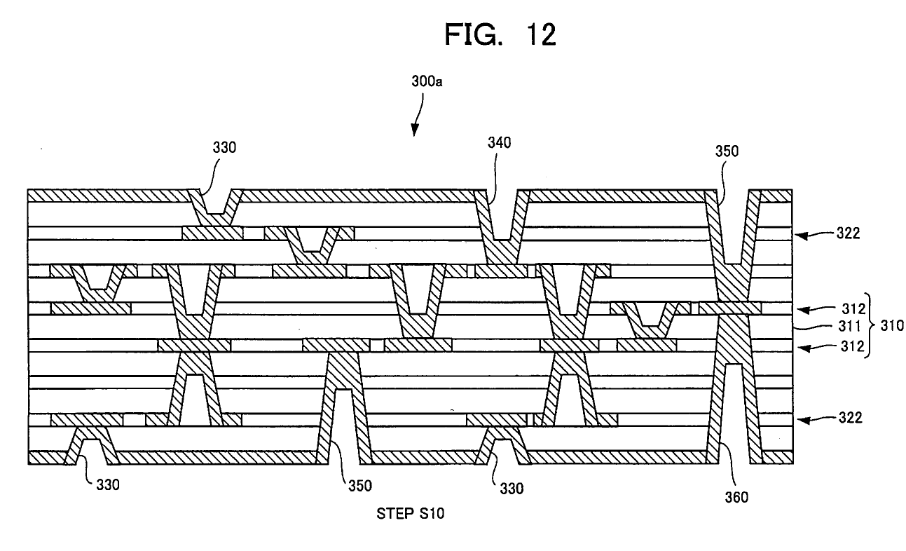

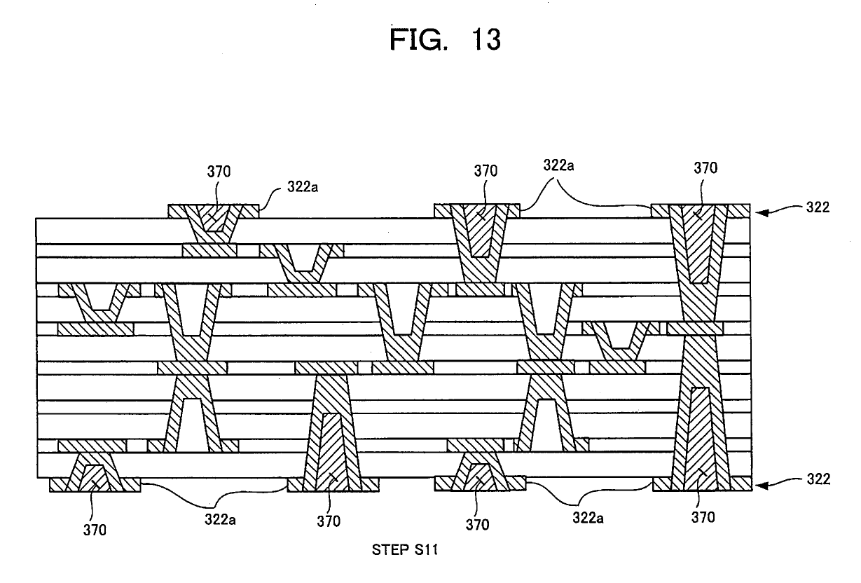

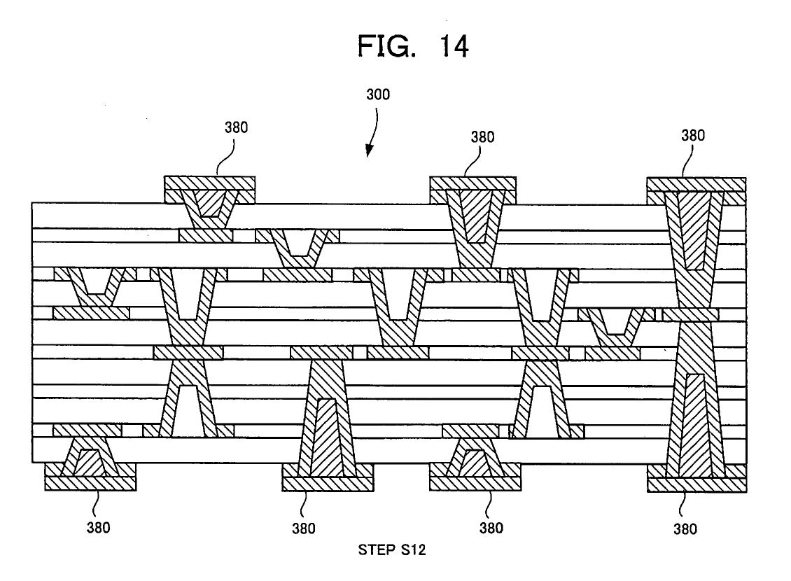

FIG. 8 is a diagram for illustrating processing in steps S1 to S3 in the method of manufacturing the multilayer wiring board 300. FIG. 9 is a diagram for illustrating processing in steps S4 to S6 in the method of manufacturing the multilayer wiring board 300. FIG. 10 is a diagram for illustrating processing in steps S7 and S8 in the method of manufacturing the multilayer wiring board 300. FIG. 11 is a diagram for illustrating a processing in step S9 in the method of manufacturing the multilayer wiring board 300. FIG. 12 is a diagram for illustrating processing in step S10 in the method of manufacturing the multilayer wiring board 300. FIG. 13 is a diagram for illustrating processing in step S11 in the method of manufacturing the multilayer wiring board 300. FIG. 14 is a diagram for illustrating processing in step S12 in the method of manufacturing the multilayer wiring board 300.

In the manufacturing method illustrated in FIGS. 8 to 14, first, in step S1, a core layer 310 having a base insulating layer 311 and conductor layers 312′, each of which is to form a conductor pattern of a wiring layer later, formed on the opposite front and back surfaces of the base insulating layer 311 is prepared. Then, in step S2, a hole is formed in the core layer 310 by laser beam machining from the side of a front surface 300a of the multilayer wiring board 300 to be manufactured illustrated in FIG. 3. In this example based on FIG. 3, in step S2, one hole that penetrates through one insulating layer from the conductor layer 312′ of the core layer 310 closer to the front surface 300a to the conductor layer 312′ of the core layer 310 closer to a back surface 300b of the multilayer wiring board 300 is formed.

In this embodiment, preceding the laser beam machining, a part of the conductor layer 312′ of the core layer 310 closer to the front surface 300a at which a hole is to be formed is removed by etching. In the laser beam machining, the laser beam is applied to the part from which the conductor layer 312′ is removed. The laser beam penetrating into the insulating layer 311 by forming a hole therein and is blocked at the conductor layer 312′ of the core layer 310 on the back surface 300b. In this way, the hole that penetrates through one insulating layer from the conductor layer 312′ closer to the front surface 300a to the conductor layer 312′ of the core layer 310 closer the back surface 300b is formed.

Then, in step S3, the inner surface of the hole formed in step S2 is plated with a conductor, thereby forming an adjacent via 330 that covers the inner surface of the hole with the conductor and electrically connects wiring layers 312 forming the front and back surfaces of the core layer 310 illustrated in FIG. 3.

Then, in step S4, first, conductor patterns 312a of the wiring layers 312 forming the front and back surfaces of the core layer 310 are formed by a subtractive process. In this subtractive process, first, a mask is formed over the necessary part of each conductor film 312′. Then, the unnecessary part is removed by etching to form the conductor pattern 312a. According to the subtractive process, if the adjacent via 330 formed in step S3 described above is covered with the mask, the conductor pattern 312a can be easily formed without damaging the adjacent via 330.

In step S4, next, an insulating layer 321 having a conductor layer 3221 to form a conductor pattern of a wiring layer later formed on a surface thereof is stacked on each of the front and back surfaces of the core layer 310 on which the conductor pattern 312a described above is formed in such a manner that the insulating layer 321 faces the core layer 310, and the insulating layers 321 and the core layer 310 are integrated by heating under pressure. As a result of the heating under pressure, the insulating material forming the insulating layers 321 penetrates into the gaps between the conductors of the conductor patterns 312a on the front and back surfaces of the core layer 310. As a result, the wiring layers 312 of the core layer 310, each of which is composed of the conductor pattern 312a and an insulating part 312b filling the gaps between the conductors of the conductor pattern 312a, are formed. Furthermore, the insulating material forming the insulating layers 321 penetrates into the recess of the adjacent via 330 to fill the recess.

Then, in step S5, a hole is formed in the stack formed in step S4 described above from the side of the front surface 300a of the multilayer wiring board 300 to be manufactured illustrated in FIG. 3 by etching and laser beam machining described above. In this example based on FIG. 3, in step S5, there are formed one hole that penetrates through one insulating layer from the conductor layer 322′ of the stack closer to the front surface 300a to the wiring layer 312a of the core layer 310 closer to the front surface 300a and three holes that penetrates through two insulating layers from the conductor layer 322′ of the stack closer to the front surface 300a to the wiring layer 312b of the core layer 310 closer to the back surface 300b.

Then, in step S6, the inner surfaces of the four holes formed in step S5 are plated with a conductor, thereby forming one adjacent via 330 that electrically connects the third wiring layer 322 from the front surface 300a illustrated in FIG. 3 and the wiring layer 312 of the core layer 310 closer to the front surface 300a and three one-layer-skip vias 340 that electrically connect the third wiring layer 322 from the front surface 300a described above and the wiring layer 312 of the core layer 310 closer to the back surface 300b.

Then, in step S7, the conductor films 322′ forming the front and back surfaces of the stack after step S6 are shaped into conductor patterns 322a by the subtractive process described above. Then, an insulating layer 321 having the same conductor layer 322′ as described above formed on a surface thereof is stacked on each of the front and back surfaces of the stack on which the conductor patterns 312a are formed in such a manner that the insulating layer 321 faces the core layer 310, and the insulating layers 321 and the core layer 310 are integrated by heating under pressure. Through the stacking and integration, insulating parts 322b filling the gaps between the conductors of the conductor patterns 322a are formed, and the third wiring layer 322 from the front surface 300a and the third wiring layer 322 form the back surface 300b illustrated in FIG. 3 are formed. Furthermore, in the integration, the recess of the adjacent via 330 and the recesses of the one-layer-skip vias 340 formed in step S6 are filled with the insulating material. Then, holes are formed in the stack after the integration from both the sides of the front surface 300a and the back surface 300b of the multilayer wiring board 300 to be manufactured illustrated in FIG. 3 by etching and laser beam machining described above. In this example based on FIG. 3, in step S7, there are formed one hole that penetrates through one insulating layer from the conductor layer 322′ of the stack closer to the front surface 300a to the third wiring layer 322 from the front surface 300a described above and two holes that penetrates two insulating layers from the conductor layer 322′ of the stack closer to the back surface 300b to the wiring layer 312 of the core layer 310 closer to the back surface 300b.

Then, in step S8, the inner surfaces of the holes formed in step S7 are plated with a conductor, thereby forming one adjacent via 330 that electrically connects the second wiring layer 322 and the third wiring layer 322 from the front surface 300a illustrated in FIG. 3 and two one-layer-skip vias 340 that electrically connect the second wiring layer 322 from the back surface 300b illustrated in FIG. 3 and the wiring layer 312 of the core layer 310 closer to the back surface 300b.

In step S9, the stack after step S8 described above is subjected to the same processing as those performed in step S7 including formation of conductor patterns 322a, stacking and integration of insulating layers 321 having conductor layers 322′ and formation of holes. In step S10, the same processing as the conductor plating performed in step S8 described above is performed. Through these two steps, the second wiring layer 322 from the front surface 300a and the second wiring layer 322 from the back surface 300b illustrated in FIG. 3 are formed, and one adjacent via 330 that electrically connects the wiring layer 322 forming the front surface 300a and the second wiring layer 322 from the front surface 300a, one one-layer-skip via 340 that electrically connects the wiring layer 322 forming the front surface 300a and the third wiring layer 322 from the front surface 300a, one two-layer-skip via 350 that electrically connects the wiring layer 322 forming the front surface 300a and the wiring layer 312 of the core layer 310 closer to the front surface 300a, two adjacent vias 330 that electrically connect the wiring layer 322 forming the back surface 300b and the second wiring layer 322 from the back surface 300b, one two-layer-skip via 350 that electrically connects the wiring layer 322 forming the back surface 300b and the wiring layer 312 of the core layer 310 closer to the back surface 300b, and one three-layer-skip via 360 that electrically connects the wiring layer 322 forming the back surface 300b and the wiring layer 312 of the core layer 310 closer to the front surface 300a are formed.

Then, in step S11, the stack after the processing in step S10 is subjected to formation of conductor patterns 322a, which is the same processing as that performed in step S7, and thus, wiring layers 322 forming the front surface 300a and the back surface 300b are formed. Furthermore, the recesses of the vias opening in the wiring layers 322 forming the front surface 300a and the back surface 300b are filled with the predetermined resin material 370.

Then, finally, in step S12, conductor films 380 covering the openings of the vias filled with the resin material 370 and serving as lands are formed by conductor plating according to the subtractive process described above. In this way, the multilayer wiring board 300 illustrated in FIG. 3 is completed.

As described above, in the manufacture of the multilayer wiring board 300 according to this embodiment, conductor plating for filling the vias with a conductor, which is conventionally necessary, is unnecessary, and the number of steps and therefore the cost are reduced accordingly. In addition, in the multilayer wiring board 300 according to this embodiment, the bottoms of the two vias connecting wiring layers can be in contact with the isolated pattern in any wiring layer, and therefore, conductor plating can be optimized to prevent each via from being excessively deep, and the cost can be further reduced.

While a cellular phone has been described above as an example of the electronic device, the electronic device is not limited thereto but can be a notebook personal computer or a personal digital assistant (PDA), for example.

While the multilayer wiring board 300 in which eight wiring layers and seven insulating layers are alternately stacked has been described above as an example of the multilayer wiring board described above, the multilayer wiring board is not limited thereto but can include any number of wiring layers other than the number described above and any number of insulating layers other than the number described above.

While a configuration of the multilayer wiring board in which the recesses of the vias opening in the wiring layers forming the front and back surfaces are filled with a resin material and the openings are covered with a conductor film and a configuration of the multilayer wiring board in which the recesses of the vias opening in the wiring layers forming the front and back surface remain hollow have been described above as configurations of the multilayer wiring boards, the configuration of the multilayer wiring board is not limited to these configurations but can be a combination of the two configurations described above, for example.

Furthermore, while the conductor pattern of each wiring layer is formed by the subtractive process in which a mask is formed over the necessary part of the conductor film formed on the insulating layer, and the unnecessary part outside of the mask is removed by etching in the example described above, the method of forming the conductor pattern is not limited thereto. For example, the conductor pattern can also be formed by a full additive process in which the conductor pattern is formed by forming a mask over the part of the insulating layer other than the part on which the conductor pattern is to be formed and plating the part outside of the mask with a conductor or a semi additive process in which the conductor pattern is formed by forming a thin conductor film over the insulating layer, forming a mask over the part of the thin conductor film other than the part on which the conductor pattern is to be formed, plating the part outside of the mask with a conductor, removing the mask, and then removing the conductor over the entire area by etching by the thickness of the thin conductor film to form the conductor pattern.

According to the multilayer wiring board of the present invention, since the first via and the second via are in contact with the inner wiring layer with the bottoms thereof facing each other, the vias are electrically connected to each other while maintaining the recessed shape. Furthermore, since the two vias are electrically connected to each other, the wiring layers in which the vias open that are spaced apart from each other with multiple wiring layers interposed therebetween can be electrically connected to each other by the two vias. Conventionally, in many cases, wiring layers in such a positional relationship are electrically connected to each other by a stack of multiple vias that extend from a wiring layer to an adjacent layer through one insulating layer. According to this conventional method, the vias have a conductor covering the inner surface of a hole penetrating through one insulating layer and having the shape of a recess conforming to the inner surface, and the recess of the conductor has to be further filled with a conductor in order to electrically connect multiple vias to each other. According to the essential structure of the multilayer wiring board described above, since two vias can be electrically connected to each other simply by arranging the two vias so that the inner wiring layer is sandwiched between the bottoms of the vias, unlike the conventional method, there is no need of filling the recess of each via with a conductor, and the cost can be reduced accordingly.

According to the multilayer wiring board unit of the present invention, since the cost of the multilayer wiring board is reduced as described above, the cost of the multilayer wiring board unit can also be reduced.

According to the electronic device of the present invention, since the cost of the multilayer wiring board is reduced as described above, the cost of the electronic device can also be reduced.

Thus, according to the present invention, the cost of the multilayer wiring board, the multilayer wiring board unit and the electronic device can be reduced.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention have been described in detail, it should be understood that the various changes, substitutions, and alterations could be made hereto without departing from the spirit and scope of the invention.

What is claimed is:

1. A multilayer wiring board, comprising:
a plurality of wiring layers;
a plurality of insulating layers that are stacked alternately with the plurality of wiring layers to form a multilayer structure;
a first via made of a conductor covering an inner surface of a hole penetrating through a plurality of insulating layers and having a bottom on an inner wiring layer of the plurality of wiring layers, the inner wiring layer having a plurality of insulating layers on both the upper and lower sides thereof in the multilayer structure, and the first via having the shape of a recess conforming to the inner surface; and
a second via made of a conductor covering an inner surface of a hole penetrating through a plurality of insulating layers in the direction opposite to the direction of the hole for the first via and having a bottom on the inner wiring layer at a position corresponding to the bottom of the hole for the first via, the second via having the shape of a recess conforming to the inner surface.

2. The multilayer wiring board according to claim 1, wherein the first via and the second via are recesses that are formed in the multilayer wiring board and filled with an insulating material of the insulating layer.

3. The multilayer wiring board according to claim 1, wherein the first via and the second via are recesses that are exposed on either a front surface or a back surface of the multilayer wiring board and remain hollow.

4. The multilayer wiring board according to claim 1, wherein the first via and the second via are recesses that are exposed on either a front surface or a back surface of the multilayer wiring board, filled with a resin, and covered with a conductor film.

5. The multilayer wiring board according to claim 1, wherein the wiring layers are formed by a subtractive process.

6. A multilayer wiring board unit, comprising:
a multilayer wiring board, comprising:
a plurality of wiring layers,
a plurality of insulating layers that are stacked alternately with the plurality of wiring layers to form a multilayer structure,
a first via made of a conductor covering an inner surface of a hole penetrating through a plurality of insulating layers and having a bottom on an inner wiring layer of the plurality of wiring layers, the inner wiring layer having a plurality of insulating layers on both the upper and lower sides thereof in the multilayer structure, and the first via having the shape of a recess conforming to the inner surface, and
a second via made of a conductor covering an inner surface of a hole penetrating through a plurality of insulating layers in the direction opposite to the direction of the hole for the first via and having a bottom on the inner wiring layer at a position corresponding to the bottom of the hole for the first via, the second via having the shape of a recess conforming to the inner surface; and
an electronic component mounted on the multilayer wiring board.

7. An electronic device, comprising:
a multilayer wiring board, comprising:
a plurality of wiring layers,
a plurality of insulating layers that are stacked alternately with the plurality of wiring layers to form a multilayer structure,
a first via made of a conductor covering an inner surface of a hole penetrating through a plurality of insulating layers and having a bottom on an inner wiring layer of the plurality of wiring layers, the inner wiring layer having a plurality of insulating layers on both the upper and lower sides thereof in the multilayer structure, and the first via having the shape of a recess conforming to the inner surface, and
a second via made of a conductor covering an inner surface of a hole penetrating through a plurality of insulating layers in the direction opposite to the direction of the hole for the first via and having a bottom on the inner wiring layer at a position corresponding to the bottom of the hole for the first via, the second via having the shape of a recess conforming to the inner surface;
an electronic component mounted on the multilayer wiring board; and
a housing that houses the multilayer wiring board on which the electronic component is mounted.
